(19) United States
(12) Patent Application Publication
(10) Pub. No.: US 2010/0093174 A1
(43) Pub. Date: Apr. 15, 2010

(54) METHOD OF MANUFACTURING LOW-K DIELECTRIC FILM, AND FORMATION OF AIR-GAP USING THE LOW-K DIELECTRIC FILM

(76) Inventor: Jae-Young Yang, Suwon-si (KR)

Correspondence Address: SHERR & VAUGHN, PLLC, 620 HERNDON PARKWAY, SUITE 320, HERNDON, VA, 20170, US

(21) Appl. No.: 12/565,922

(22) Filed: Sep. 24, 2009

(30) Foreign Application Priority Data
Oct. 15, 2008 (KR) 10-2008-0101130

(51) Int. Cl. H01L 21/3105; H01L 21/312; H01L 21/306

(52) U.S. Cl. 438/692; 438/781; 438/763; 257/E21.242; 257/E21.259; 257/E21.23

(57) ABSTRACT

A dielectric film, a method of manufacturing a dielectric film and a method of forming an air-gap. A method of manufacturing a low-k dielectric film may include introducing TMS and 3,3-dimethyl-1-butene into a plasma deposition reactor, polymerizing TMS and 3,3-dimethyl-1-butene using plasma generated in a reactor to deposit an insulation film over a substrate disposed in a reactor and/or subjecting a deposited insulation film to heat treatment concurrently with an inductively coupled plasma (ICP) process. A dielectric film may have a dielectric constant up to approximately 3. A method of forming an air-gap may include depositing a first insulation film over a surface of a patterned substrate, depositing a decahydronaphthalene layer over a portion of a first insulation film, subjecting a patterned substrate to a polishing process, forming a second insulation film, and/or subjecting a second insulation film to heat treatment concurrently with an ICP process.

The present application claims priority under 35 U.S.C. 119 to Korean Patent Application No. 10-2008-0101130 (filed on Oct. 15, 2008) which is hereby incorporated by reference in its entirety.

### BACKGROUND

Embodiments relate to electronic devices and methods of manufacturing thereof. Some embodiments relate to an insulation film and methods of forming thereof, and a method of forming an air-gap using a fabricated dielectric film.

A large-scale integration (LSI) apparatus having a CPU, memory and a system LSI may use a carbon based silicon oxide film as an interlayer dielectric film. A carbon based silicon oxide film may reduce interconnection capacity. However, signal delay may be caused.

A variety of silicon carbide films with different compositions may be used. For example, a silicon carbide film may contain silicon Si, carbon C and hydrogen H. However, a silicon carbide film containing silicon Si, carbon C and hydrogen H may have relatively high water and/or oxygen absorption. Therefore, film stress and/or dielectric properties may be relatively frequently altered upon exposure to air. A silicon carbide film may also exhibit relatively high leakage current as well as relatively poor electric isolation.

Technologies for preventing moisture and/or oxygen from passing through a surface of a film have been developed. For example, a surface of a film may be treated using an inert plasma gas. However, while this approach may relatively improve surface qualities of a film, internal features of a silicon-carbon-hydrogen (SiCH) film may not be enhanced. As a result, the film may still exhibit relatively high leakage current and/or relatively poor electric isolation. A silicon carbide film may have a dielectric constant between approximately 4.5 to 5.

Silicon carbide films with different compositions may also include, for example, a silicon carbide film containing Si, C, N and H, a silicon carbide film containing Si, C, O and H, and so forth. Compared to a SiCH film, these silicon carbide films may exhibit relatively low leakage current and relatively good electric isolation. However, a SiOCH film may have a dielectric constant of approximately 4.2 according to rate of oxygen relative to other compositions.

Because the dielectric constant of an Inter-Layer Dielectric (ILD) material should be reduced so as to enhance the performance of electronic devices, fore example semiconductor integrated circuits, there remains a need for relatively thin films having relatively low dielectric constants, for example having dielectric constants up to approximately 3. There is also a need to manufacture and use such thin films.

### SUMMARY

Embodiments relate to a method of manufacturing an insulation film with a relatively low dielectric constant (a low-k dielectric film) and a method for forming an air-gap using a fabricated low-k dielectric film in accordance with embodiments.

According to embodiments, a method of manufacturing a dielectric insulation film may include manufacturing a film having a relatively low dielectric constant, for example approximately 2.4. In embodiments, a low-k dielectric film may be useful for a semiconductor device. In embodiments, a method of manufacturing a dielectric insulation film may include deposition of a plasma polymerized SiCOH—CHₓ film. In embodiments, a dielectric insulation film may be deposited using a plasma enhanced chemical vapor deposition (PECVD) apparatus equipped with a dual bubbler. In embodiments, a method of manufacturing a dielectric insulation film may include performing an inductively coupled plasma-rapid thermal annealing (ICP-RTA).

According to embodiments, a method of manufacturing a dielectric film may include introducing trimethylsilane (TMS) and 3,3-dimethyl-1-butene into a plasma deposition reactor. In embodiments, a method of manufacturing a dielectric film may include polymerizing TMS and 3,3-methyl-1-butene using plasma generated in a reactor so as to deposit an insulation film over a substrate disposed in a reactor. In embodiments, a method of manufacturing a dielectric film may include subjecting a deposited insulation film to heat treatment concurrently with an inductively coupled plasma (ICP) process.

According to embodiments, a method of forming an air-gap may include using a fabricated dielectric insulation film in accordance with embodiments. In embodiments, a method of forming an air-gap may include using a fabricated low-k dielectric film in accordance with embodiments. In embodiments, a method of forming an air-gap may include preparing a patterned substrate. A first insulation film may be deposited over a surface of a patterned substrate in accordance with embodiments.

According to embodiments, a method of forming an air-gap may include depositing a decahydronaphthalene layer over a surface of a substrate having a first insulation film deposited thereover. In embodiments, a decahydronaphthalene layer may be deposited using a chemical vapor deposition (CVD) process. In embodiments, a decahydronaphthalene layer may fill a gap of a patterned substrate.

According to embodiments, a method of forming an air-gap may include subjecting a treated substrate to a chemical mechanical polishing (CMP) process. In embodiments, planarization of a decahydronaphthalene layer and a first insulation film formed over a substrate may be accomplished, and may be in sequential order. Polymerization of TMS and 3,3-dimethyl-1-butene may be performed in accordance with embodiments.

According to embodiments, a second insulation film may be deposited over a substantially planar substrate surface and may be deposited over polymerized TMS and 3,3-dimethyl-1-butene. In embodiments, a method of forming an air-gap may include subjecting a deposited second insulation film to heat treatment concurrently with an ICP process. In embodiments, out-gassing of a decahydronaphthalene layer disposed in a gap of a substrate through a second insulation film may be enabled, resulting in formation of the air-gap.

### DRAWINGS

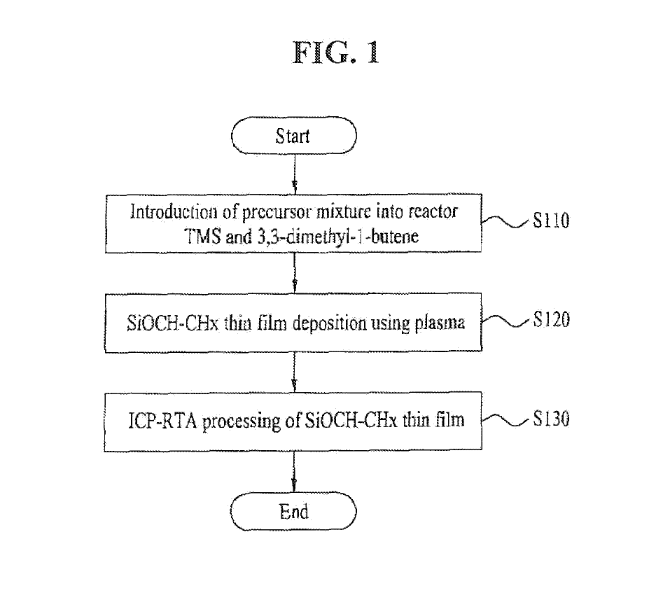

Example FIG. 1 is a flow chart illustrating a method of manufacturing a low-k dielectric film in accordance with embodiments.

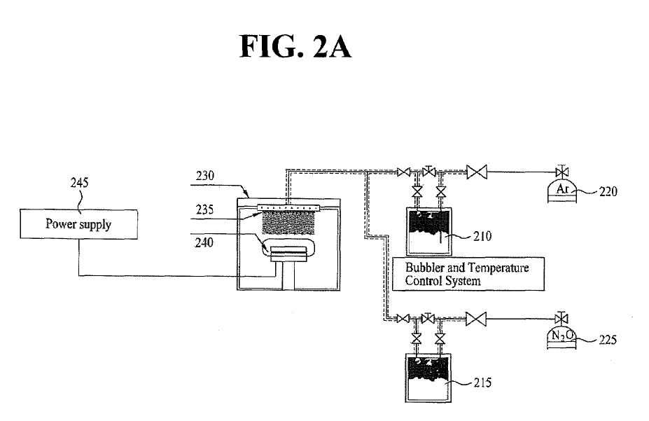

Example FIG. 2A is a schematic view illustrating a PECVD apparatus that may be used to fabricate a low-k dielectric film in accordance with embodiments.

Example FIG. 2B is a schematic view illustrating an ICP-RTA apparatus that may be used to fabricate a low-k dielectric film in accordance with embodiments.

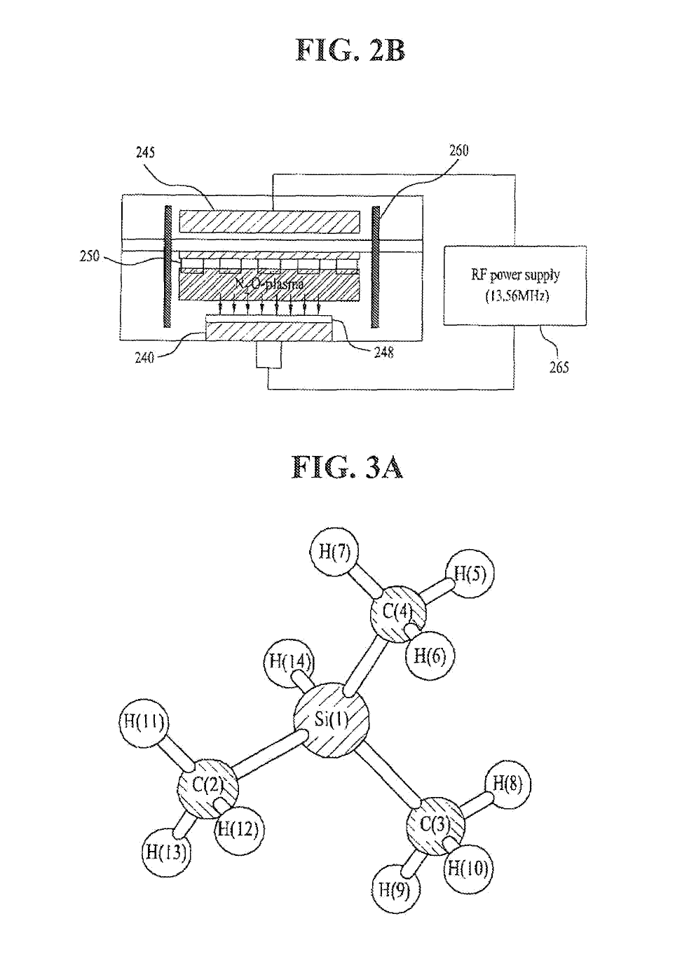

Example FIG. 3A illustrates a structure of TMS as a precursor in accordance with embodiments.

Example FIG. 3B illustrates a structure of 3,3-dimethyl-1-butene as a precursor in accordance with embodiments.

Example FIG. 3C illustrates a structure of polymerizing TMS and 3,3-dimethyl-1-butene in accordance with embodiments.

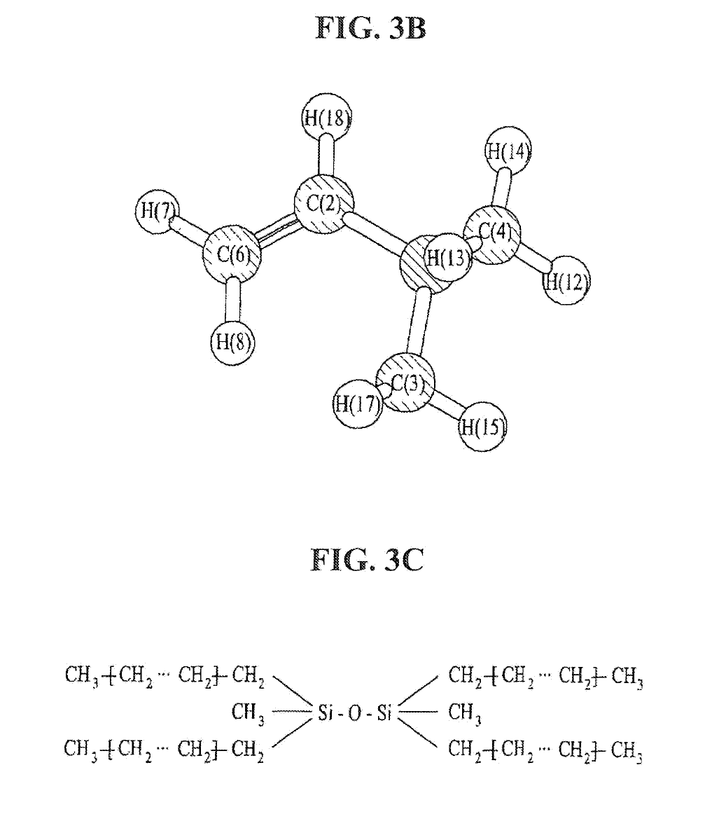

Example FIG. 4 illustrates dielectric constants of a dielectric film fabricated in accordance with embodiments.

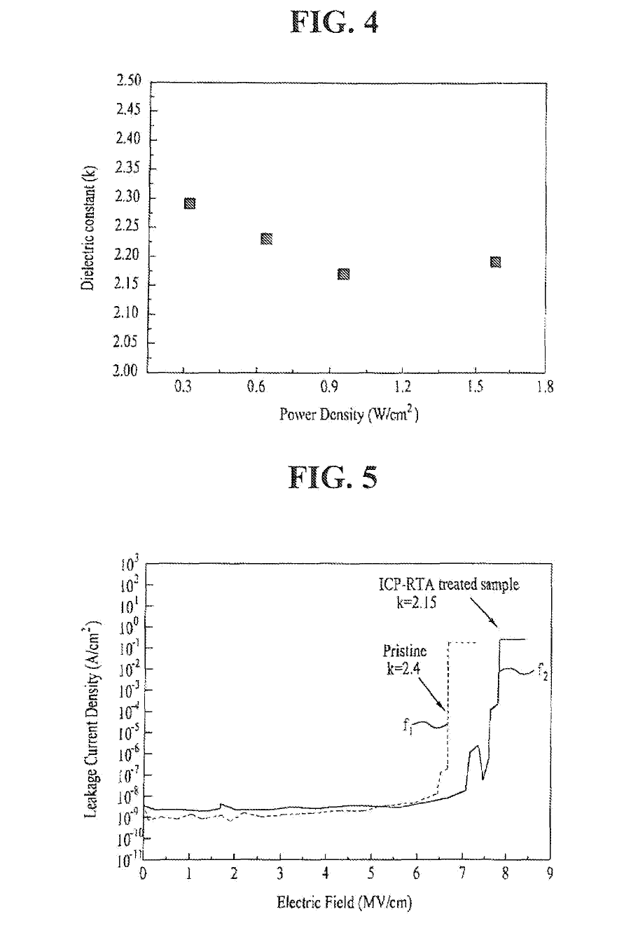

Example FIG. 5 illustrates leakage current densities of a dielectric film before and after ICP-RTA processing in accordance with embodiments.

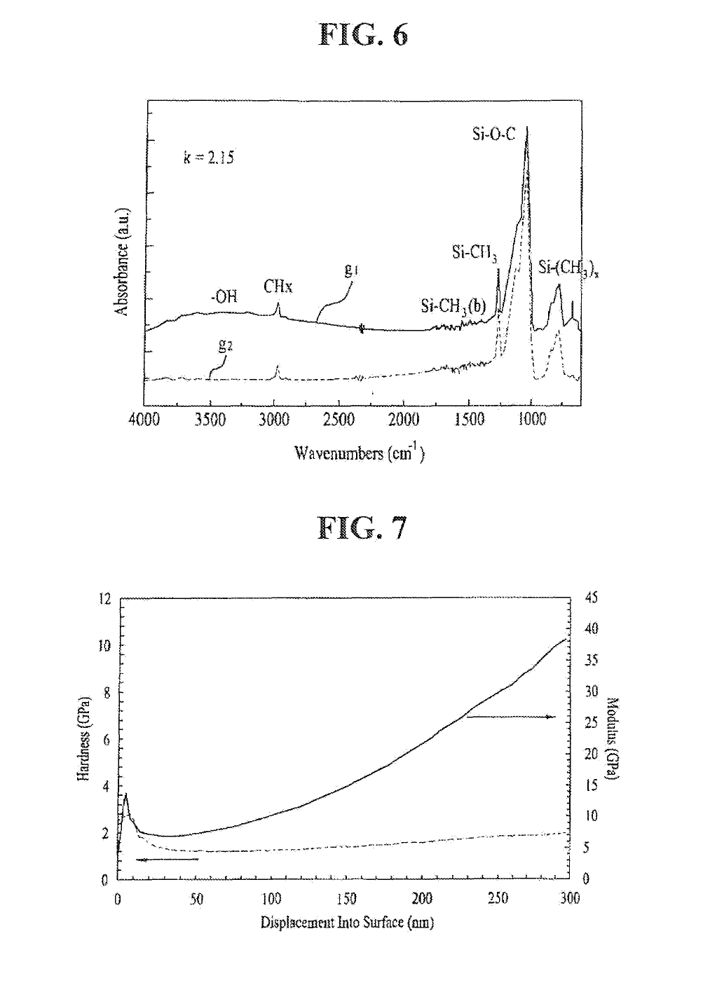

Example FIG. 6 illustrates graphs having analysis results of a chemical structure of a dielectric film before and after ICP-RTA processing in accordance with embodiments.

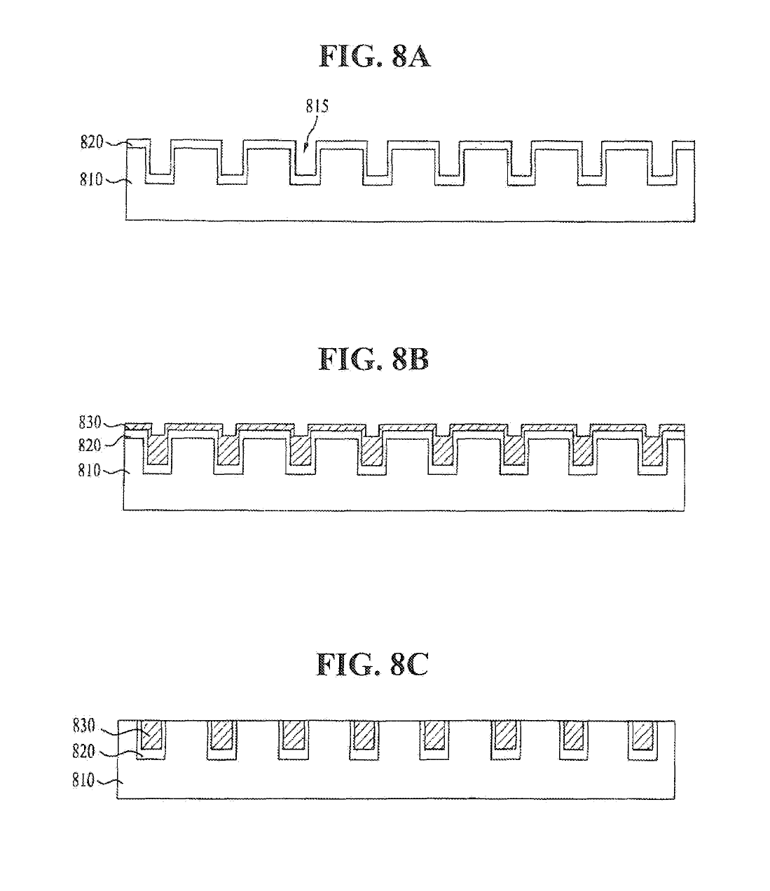

Example FIG. 7 illustrates hardness and elastic modulus of a dielectric film after ICP-RTA processing in accordance with embodiments.

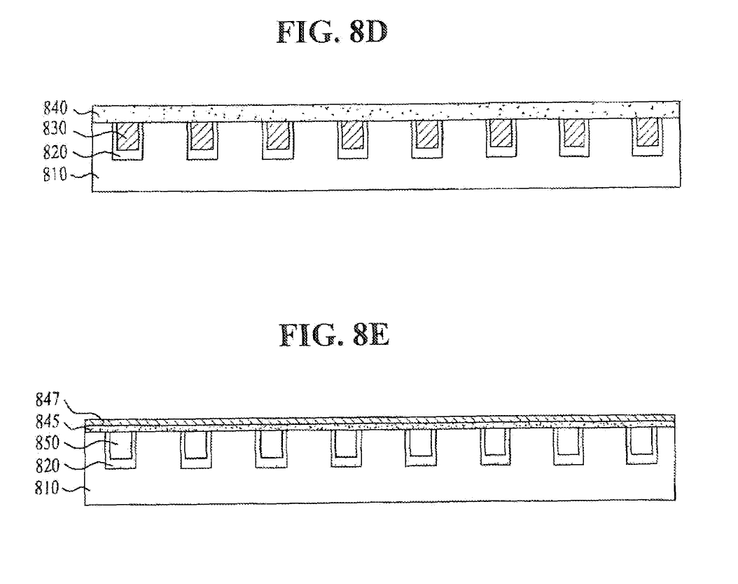

Example FIG. 8A to FIG. 8E are cross-sectional views illustrating a method of forming air-gaps using a dielectric film fabricated in accordance with embodiments.

### DESCRIPTION

Embodiments relate to a method of manufacturing an insulation film having a relatively low dielectric constant. Referring to example FIG. 1, a method of manufacturing a low-k dielectric film in accordance with embodiments is illustrated. Referring to example FIG. 2A, a PECVD apparatus that may be used to fabricate a low-k dielectric film according embodiments is illustrated.

According to embodiments, tetramethlysilane (TMS) may be used as a precursor solution and may be housed in a first bubbler 210. In embodiments, 3,3-dimethyl-1-butene may be housed in a second bubbler 215. In embodiments, a combination of first bubbler 210 and second bubbler 215 may refer to a dual bubbler.

According to embodiments, a first transport part 220 may house a first carrier gas, for example Ar, and a second transport part 225 may house a second carrier gas, for example N₂O. In embodiments, precursor solutions, for example TMS and 3,3-dimethyl-1-butene, may be heated and evaporated. In embodiments, evaporated TMS and 3,3-dimethyl-1-butene may be introduced into a reactor 230 for plasma deposition using Ar and/or N₂O as carrier gases, respectively (e.g., FIG. 1 Step S110).

According to embodiments, introduced TMS and 3,3-dimethyl-1-butene may be provided to a substrate, such as substrate 240 which may be a wafer located inside a reactor, through a showerhead 235 of reactor 230. In embodiments, substrate 240 may be provided with TMS and 3,3-dimethyl-1-butene (e.g., FIG. 1 Step S120) using plasma generated in reactor 230. In embodiments, the temperature of substrate 240 may range between approximately 300° C. to 400° C. during deposition. In embodiments, RF power may be provided by power supply 245 and plasma may be used during deposition at a density between approximately 0.1 W/cm² to 1.5 W/cm².

According to embodiments, TMS and 3,3-dimethyl-1-butene may polymerize. In embodiments, an insulation film deposited over substrate 240 may have a structure including SiOCH—CHₓ. In embodiments, X may be a natural number and an insulation film may have a deposition thickness between approximately 0.4 μm to 0.5 μm.

Referring to example FIG. 3A, a structure of TMS as a precursor is illustrated in accordance with embodiments. Referring the example FIG. 3B, a structure of 3,3-dimethyl-1-butene as a precursor is illustrated in accordance with embodiments. Referring to FIG. 3C, a structure of polymerizing TMS and 3,3-dimethyl-1-butene is illustrated in accordance with embodiments.

According to embodiments, precursors TMS and 3,3-dimethyl-1-butene introduced into reactor 230 may be activated and/or degraded into reactive species by plasma. In embodiments, precursors may be condensed over substrate 240. In embodiments, using TMS and 3,3-dimethyl-1-butene as precursors may increase the relative number of CHₓ groups, which may decreases a dielectric constant to below approximately 2.4.

Referring to example FIG. 2B, a schematic view illustrates an ICP-RTA apparatus that may be used for fabricating a low-k dielectric film in accordance with embodiments. According to embodiments, a deposited insulation film having a SiOCH—CHₓ structure may be subjected to ICP-RTA using an ICP-RTA apparatus, for example as shown in FIG. 2B (e.g., FIG. 1 Step 130). In embodiments, halogen lamp 250 may emit light with a wavelength between approximately 2 μm to 5 μm and may be disposed around substrate 240 deposited with insulation film 248 having a SiOCH—CHₓ structure. In embodiments, halogen lamp 250 may generate heat for treatment of insulation film 248 between approximately 350° C. to 450° C.

According to embodiments, N₂O plasma may be concurrently generated to substrate 240 using RF power provided by RF power supply 265 and 6-turn Cu antenna 245. In embodiments, insulation film 248 having a SiOCH—CHₓ structure may be subjected to a plasma process. In embodiments, a frequency of the RF power supplied to the Cu antenna may range from between approximately 13 MHz to 14 MHz. In embodiments, a frequency of the RF power supplied to plasma guide 260 may range between approximately 100 KHz to 150 KHz.

According to embodiments, insulation film 248 having a SiOCH—CHₓ structure may be subjected to heat treatment concurrently with plasma treatment. In embodiments, heat treatment may separate CH_{y} bonded to Si in insulation film 248 having a SiOCH—CHₓ structure wherein y may be equal to or less than x. In embodiments, oxygen contained in N₂O plasma may be disposed in the empty space to substitute for CH_{y} separated by heat treatment, so as to increase the relative strength of insulation film 248.

Referring to example FIG. 4, dielectric constants are illustrated for a dielectric film fabricated in accordance with embodiments, for example by the method illustrated in FIG. 1. According to embodiments, when a plasma density used for polymerization of TMS and 3,3-dimethyl-1-butene increases, the dielectric constant may be reduced for example to approximately 2.15.

Referring to example FIG. 5, leakage current densities are illustrated for a dielectric film before and after ICP-RTA processing (f1 and f2, respectively) in accordance with embodiments. According to embodiments, through leakage current feature of a dielectric film with a k of approximately 2.15, breakdown voltage properties after ICP-RTA processing may be relatively improved.

Referring to example FIG. 6, graphs illustrate analysis results of a chemical structure of a dielectric film before and after ICP-RTA processing (g1 and g2, respectively) in accordance with embodiments. According to embodiments, analyzing the chemical structure of a dielectric film using infrared spectroscopy may demonstrate that both chemical structures g1 and g2 may be stretched at the same frequency. Therefore, a bonding structure of a dielectric film may be substantially similar before and after ICP-RTA processing of a plasma deposited insulation film in accordance with embodiments.

Referring to example FIG. 7, hardness and/or elastic modulus of a dielectric film after ICP-RTA processing in accordance with embodiments are illustrated. According to embodiments, hardness and elastic modulus of a dielectric film after IPC-RTA processing may be approximately 1.25 GPa and 10 GPa, respectively. Referring to FIG. 4 and FIG. 7, a plasma polymerized dielectric film fabricated by a method in accordance with embodiments may have relatively improved features including dielectric property, thermal stability, substantially un-changeable chemical bonding structure, strength (e.g., hardness) and/or elastic modulus.

According to embodiments, using linear type organic and inorganic precursor materials may provide a low-k dielectric film. In embodiments, post-treatment using an ICP-RTA apparatus may enable relative improvement in dielectric constant and/or mechanical strength of a plasma polymerized dielectric film.

Embodiments relate to a method of forming an air-gap using a fabricated low-k dielectric film in accordance with embodiments. Referring to example FIG. 8A to FIG. 8E, cross-sectional views illustrate a process of forming air-gaps using a dielectric film fabricated in accordance with embodiments, for example by the method illustrated in FIG. 1.

Referring to FIG. 8A, undoped silicate glass (“USG”) layer 820 may be deposited over a patterned wafer 810 (e.g., a substrate). According to embodiments, layer 820 may have a thickness between approximately 5 nm to 10 nm. In embodiments, patterned substrate 810 may be a metal pattern, a trench pattern and/or a contact hole pattern applied to the substrate. USG layer 820 may be formed over an inner surface of gap 815 in patterned substrate 810 as well as other surface(s) of the substrate in accordance with embodiments.

Referring to FIG. 8B, plasma polymerized decahydronaphthalene (“DHN”) layer 830 may be deposited over substrate 810 having USG layer 820 thereover by chemical vapor deposition (CVD). In embodiments, plasma polymerized DHN layer 830 may be filled over gap 815 of substrate 810 and may also be formed over USG layer 820. In embodiments, plasma polymerized DHN layer 830, in an initially deposited state, may be thermally unstable and may have a relatively small molecular size, which may exhibit relatively excellent gap-filling capacity.

Referring to FIG. 8C, a CMP process may be conducted to successively planarize at least a portion of DHN layer 830 and USG layer 820 formed over substrate 810 to form a substantially planar surface. In embodiments, DHN layer 830 and USG layer 820 may be planarized in order, and may be removed until substrate 810 is exposed.

Referring to FIG. 8D, low-k dielectric film 840 (e.g., including a k between approximately 2.7 and 3) may be deposited over planar substrate 810 in accordance with embodiments, for example according to processes S110 and S120 illustrated in FIG. 1. In embodiments, deposited dielectric film 840 may be subjected to a rapid thermal annealing (RTA) heat treatment at approximately between 350° C. to 450° C., and may be treated concurrently with an ICP process.

According to embodiments, deposited dielectric film 840 may form a film with a porous structure 845 (e.g., “porous film”) by heat treatment in accordance with embodiments. In embodiments, heat treatment may enable DHN layer 830 disposed in gap 815 of a substrate to be out-gassed through porous film 845, resulting in air-gap 850 formed approximately at the outgassed space. In embodiments, air-gap 850 may drastically relatively reduce parasitic capacitance between wires, thereby efficiently decreasing influence on RC delay and/or signal distortion in driving a device.

According to embodiments, an ICP process using He and N₂O gases may be performed for approximately between 5 seconds to 60 seconds so as to form an improved layer 847. In embodiments, layer 847 may have a thickness of approximately 5 nm to 10 nm and may be formed over a portion of the substrate, such as over a surface of porous film 845. In embodiments, relative improvement of insulation properties of deposited porous film 845 and fixation and/or removal of residues from porous film 845 may be provided.

According to embodiments, a plasma polymerized film formed by ICP-PECVD, which may be thermally unstable (e.g., substantially completely decomposed at less than approximately 250° C.) may be used as a sacrificial layer to fabricate an air-gap through heat treatment. In embodiments, a plasma polymerized film used may only include organic materials. In embodiments, DHN having thermally unstable CH₂ groups in relatively large numbers may be used as a precursor to fabricate porous film 845 by performing RTA-IPC treatment. In embodiments, conformal air-gap 850 may be formed as illustrated in FIG. 8E, while decreasing a dielectric constant of porous film 845.

According to embodiments, a method of manufacturing a low-k dielectric film may provide an insulation film with a relatively low dielectric constant using TMS and 3,3-dimethyl-1-butene as precursors. In embodiments, a method of manufacturing a low-k dielectric film may effectively relatively improve a dielectric constant and mechanical properties of an insulation film by post-treatment using an ICP-RTA apparatus.

According to embodiments, a method of forming an air-gap using a fabricated low-k dielectric film in accordance with embodiments may fabricate an insulation film using DHN having thermally unstable CH₂ groups in large numbers as a precursor by performing RTA-IPC treatment. In embodiments, a fabricated insulation film may be employed to form a conformal air-gap, while efficiently decreasing a dielectric constant of the insulation film.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
introducing trimethylsilane and 3,3-dimethyl-1-butene to a plasma deposition reactor having a substrate disposed therein;
polymerizing the trimethylsilane and 3,3-dimethyl-1-butene using plasma generated in the reactor to deposit an insulation film over a surface of the substrate; and
subjecting said deposited insulation film to a heat treatment and an inductively coupled plasma process.

2. The method of claim 1, wherein introducing the trimethylsilane and 3,3-dimethyl-1-butene comprises:
housing the trimethylsilane in a first bubbler;
housing the 3,3-dimethyl-1-butene in a second bubbler;
evaporating and introducing the trimethylsilane to the reactor using a first carrier gas housed in a first transport part; and
evaporating and introducing the 3,3-dimethyl-1-butene to the reactor using a second carrier gas housed in a second transport part.

3. The method of claim 1, wherein depositing said insulating film is performed by polymerizing the trimethylsilane and 3,3-dimethyl-1-butene using plasma comprising a density between approximately 0.1 W/cm³ to 1.5 W/cm³.

4. The method of claim 3, wherein the temperature of the substrate is between approximately 300° C. to 400° C.

5. The method of claim 1, wherein said deposited insulation film comprises the formula SiOCH—CHₓ.

6. The method of claim 5, wherein:
X is a natural number; and
the thickness of said deposited insulation film is between approximately 0.4 μm to 0.5 μm.

7. The method of claim 1, wherein said heat treatment and inductively coupled plasma process are concurrently performed comprising an inductively coupled plasma-rapid thermal annealing apparatus.

8. The of claim 7, wherein said concurrent heat treatment and inductively coupled plasma process comprise generating heat using a halogen lamp, wherein:
said halogen lamp emits light with a wavelength between approximately 2 μm to 5 μm, and
said deposited insulation film is heated at a temperature between approximately 350° C. to 450° C.

9. The method of claim 8, wherein said concurrent heat treatment and inductively coupled plasma process comprises heat treating said deposited insulation film and at substantially the same time generating N₂O plasma in the reactor to treat said deposited insulation film with the generated plasma.

10. The method of claim 9, wherein a frequency of RF power supplied to an antenna ranges between approximately 13 MHz to 14 MHz and a frequency of RF power supplied to a plasma guide ranges between approximately 100 KHz to 150 KHz.

11. The method of claim 9, wherein:
said deposited insulation film comprises the formula SiOCH—CHₓ;
heat treatment separates CH_{y} bonded to Si to form an empty space, wherein where y is equal to or less than x; and
oxygen contained in said N₂O plasma is disposed into said empty space.

12. The method of claim 1, wherein a low-k dielectric film is formed comprising a dielectric constant up to approximately 3.

13. A method comprising:
providing a patterned substrate;
depositing a first insulation film over a surface of the patterned substrate;
depositing a decahydronaphthalene layer at least over a portion of the patterned substrate comprising said first insulation film;
subjecting said patterned substrate to a polishing process to planarize at least a portion of one of said decahydronaphthalene layer and first insulation film to form a substantially planar surface;
polymerizing trimethylsilane and 3,3-dimethyl-1-butene to form a second insulation film over at least a portion of said substantially planar surface; and
subjecting said deposited second insulation film to a heat treatment and an inductively coupled plasma process.

14. The method of claim 13, wherein:
depositing said decahydronaphthalene layer comprises a chemical vapor deposition process to fill a gap of said patterned substrate;
said polishing process comprises a chemical mechanical polishing process applied in sequential order;
said heat treatment and inductively coupled plasma process are concurrently performed; and
at least a portion of said decahydronaphthalene layer filled in the gap outgasses through said second insulation film to form an air-gap.

15. The method of claim 13, wherein the deposition of said first insulation film comprises depositing an undoped silicate glass layer over a surface of the substrate.

16. The method of claim 13, wherein planarization of said decahydronaphthalene layer and first insulation film comprises sequentially planarizing said decahydronaphthalene layer and first insulation film until a portion of the substrate is exposed, followed by removal of substantially all said decahydronaphthalene layer and first insulation film not disposed in a gap.

17. The method of claim 13, wherein forming an air-gap comprises a rapid thermal annealing heat treatment at between approximately 350° C. to 450° C. concurrently with said inductively coupled plasma process.

18. The method of claim 17, wherein a surface of said second insulation film is subjected to said inductively coupled plasma process using at least one of He and N₂O gases.

19. The method of claim 18, wherein said inductively coupled plasma process is performed between approximately 5 seconds to 60 seconds.

20. The method of claim 19, wherein a layer is formed having a thickness of between approximately 5 nm to 10 nm over a portion of the substrate.
